(19) United States
(12) Patent Application Publication
(10) Pub. No.: US 2023/0018294 A1
(43) Pub. Date: Jan. 19, 2023

(54) Systems and Methods for Thermoelectric Body Cooling

(71) Applicant: Thomas M. Maurice, Brookfield, WI (US)

(72) Inventor: Thomas M. Maurice, Brookfield, WI (US)

(21) Appl. No.: 17/866,221

(22) Filed: Jul. 15, 2022

Related U.S. Application Data
(60) Provisional application No. 63/222,024, filed on Jul. 15, 2021.

(51) Int. Cl. A41D 19/015; H01L 35/32; H01L 35/30

(52) U.S. Cl. CPC A41D 19/01541; H01L 35/32; H01L 35/30; A41D 2400/00

(57) ABSTRACT

Multiple embodiments of a system are disclosed to draw heat away from the body through the palm, back of the hand, or forehead using a thermoelectric device. In doing so, the core body temperature may be lessened, allowing for quicker muscle recovery and better physical performance during exercise and/or during rest breaks between periods of exercise.

### BACKGROUND OF THE INVENTION

During rigorous physical activity, the human body tends to increase in core temperature as blood circulation to muscles increases. While inevitable, an increase in body temperature leads directly to muscle fatigue and failure due to overheating of muscle enzymes. This effect is most noticeable in sports and weightlifting, where muscle fatigue and failure can significantly affect performance. Therefore, an efficient way to cool the body temperature to prevent muscle fatigue is desirable.

In the past, efforts to cool muscles have involved methods such as direct contact with a cold substance, such as ice bags, packs, baths, and wet towels. While effective in specific circumstances, these methods have significant drawbacks. For example, when ice comes into contact with the human body, it melts due to the relatively high temperature of the skin. Wet towels face a similar problem in that they eventually dry out and lose their ability to cool the body. Wet towels also face the problem of heating up due to water loss and water transfer from the towel to the body. Further, ice bags, packs, and wet towels are generally only effective in a specific area, as they are usually disposed on the specific muscle that is fatigued. In activities involving more than one muscle group, the user is thus forced to use multiple ice bags, packs, or towels or only focus on the most fatigued area and limit recovery of the other areas. Therefore, more efficient systems and methods for reducing body temperature during rigorous physical activity are desired.

One method of effectively cooling core body temperature instead of one specific area is to cool body regions containing high concentrations of Arterio-Venous Anastomoses (AVAs). AVAs, like other vasculatures, absorb and transfer heat throughout the body. However, AVAs have a larger diameter compared to other vasculatures, allowing a greater surface area for better temperature transfer to arteries and veins. In cooling these AVAs, core body temperature can be drastically reduced in surprisingly short time periods. AVAs are mostly located in regions of hair- or fur-free skin, such as the palms, soles of the feet, and the face (including the forehead). Therefore, by cooling a region of this type of skin region, core body temperature may be reduced, muscle fatigue may be prolonged, and muscle recovery rates may be increased (recovery times reduced).

This method of muscle recovery has potential applications in sports, weight lifting, injury prevention, heat stroke prevention, military training and operations, firefighting, law enforcement training and operation, job efficacy and safety for manual labor jobs, and medical and recreational temperature regulation, to name a few. Significantly, some studies show that palm cooling specifically can lead to increased weight lifting repetitions to exhaustion and a greater exercise volume, caused by delayed muscle fatigue and an anti-irritant effect during resistive exercise. (Sub Kwon et. al., Palm Cooling Delays Fatigue during High-Intensity Bench Press Exercise, Medicine and Science in Sports and Exercise (February 2020)). Importantly, these effects have been documented in both men (Sub Kwon et. al.) and women (Kwon et. al., Palm Cooling and Heating Delays Fatigue During Resistance Exercise in Women, Journal of Strength and Conditioning Research (August 2015)). Therefore, systems and methods for efficiently and safely cooling core body temperature are desired, for at least the reasons stated above.

### SUMMARY OF THE INVENTION

Embodiments of apparatus and methods according to the present invention relate generally to systems and methods utilizing wireless sensor devices and unique asset identifiers. More specifically, the present invention relates to incorporating novel systems and methods that facilitate tagging and logging assets in an efficient manner.

According to an aspect of an embodiment of an apparatus according to the present invention, the apparatus is a system for thermoelectrically cooling a human body. The system preferably includes a power source (such as one or more rechargeable or nonrechargeable batteries), a Peltier device, a fan, and a switch. The Peltier device is preferably mounted on an article to be worn on the human body (e.g., a glove, brace, sling, or headband), which may be secured by an elastic and/or adjustable strap. The Peltier device includes one or more thermally conductive layers (and may include at least one layer of thermal insulation), a thermoelectric cooler; and a heatsink. The power switch (e.g., a single throw, single pole button switch or momentary button switch) preferably controls a supply of electrical current from the power source to at least one of the Peltier device and the at least one fan.

According to another aspect of an embodiment of an apparatus according to the present invention, the apparatus may further include a non-interactive display of information, such as on/off, battery level and/or fan status.

According to an aspect of another embodiment of an apparatus according to the present invention, the apparatus is a system for thermoelectrically cooling a human body. The system preferably includes a power source (such as one or more rechargeable or nonrechargeable batteries), a Peltier device, a fan, and a switch. The Peltier device is preferably mounted in a cover or housing (which may include one or more vent or airflow holes), which may be worn on the human body or secured to a support structure, such as with a magnet. The Peltier device includes one or more thermally conductive layers (and may include at least one layer of thermal insulation), a thermoelectric cooler; and a heatsink. The power switch (e.g., a single throw, single pole button switch or momentary button switch) preferably controls a supply of electrical current from the power source to at least one of the Peltier device and the at least one fan.

According to another aspect of another embodiment of an apparatus according to the present invention, the cover may further include or support a user-interactive display to convey information, such as on/off, battery level and/or fan status, and/or to offer user control of the apparatus, such as timer functionality, and power level selection.

According to still another aspect of another embodiment of an apparatus according to the present invention, the cover may be substantially c-shaped comprising a hinge opposite an open slot. The open slot may be configured to receive a hand of the human to support the Peltier device on one of a palmar side and a dorsal side of the hand and to support the power source on the other of the dorsal side and the palmer side.

According to an aspect of an embodiment of a method according to the present invention the method includes the step of contacting an electrically operated Peltier device with an area of a living human body (e.g., a palm or forehead). The device may be supported by the human body, such as by being mounted thereto on an article such as a glove or headband. The device may be secured to or mounted substantially within a rigid cover, which may also contain a fan and a power source for supplying electrical power to the Peltier device and the fan. The method may also include the step of mounting the rigid cover to a support structure using a magnet.

### BRIEF DESCRIPTION OF THE DRAWINGS

FIG. 1 is a top plan view of a first embodiment of a system for thermoelectric body cooling according to the present invention.

FIG. 2 is a bottom plan view of the embodiment of FIG. 1.

FIG. 3 is a bottom plan view of a Peltier device that may be used in embodiments according to the present invention.

FIG. 4 is a top plan view of one embodiment of a Peltier device from FIG. 3.

FIG. 5 is a cross-sectional elevation view of the Peltier device from FIG. 3 taken along line 5-5.

FIG. 6 is a top plan view of a second embodiment of a system for thermoelectric body cooling according to the present invention.

FIG. 7 is a cross-sectional elevation view of a Peltier device from the embodiment of FIG. 6 taken along line 7-7.

FIG. 8 is a top plan view of a third embodiment of a system for thermoelectric body cooling according to the present invention.

FIG. 9 is a cross-sectional elevation view of a Peltier device from the embodiment of the system in FIG. 8.

FIG. 10 is a strap according to the system in FIG. 8.

FIG. 11 is a front elevation view of a fourth embodiment of a system for thermoelectric body cooling according to the present invention.

FIG. 12 is a right side elevation view of the system from FIG. 11.

FIG. 13 is a top plan view of a fifth embodiment of a system for thermoelectric body cooling according to the present invention.

FIG. 14 is a cross-sectional view of the embodiment of FIG. 13 taken along the 14-14 line.

FIG. 15 is a right side elevational schematic view of a sixth embodiment of a system for thermoelectric body cooling according to the present invention.

FIG. 16 is a right side elevational schematic view of a seventh embodiment of a system for thermoelectric body cooling according to the present invention.

FIG. 17 is a perspective view of the embodiment of FIG. 15.

FIG. 18 is a perspective view of the embodiment of FIG. 16, mounted for use.

### DESCRIPTION OF THE PREFERRED EMBODIMENT

Although the disclosure hereof is detailed and exact to enable those skilled in the art to practice the invention, the physical embodiments herein disclosed merely exemplify the invention which may be embodied in other specific structures. While the preferred embodiment has been described, the details may be changed without departing from the invention, which is defined by the claims.

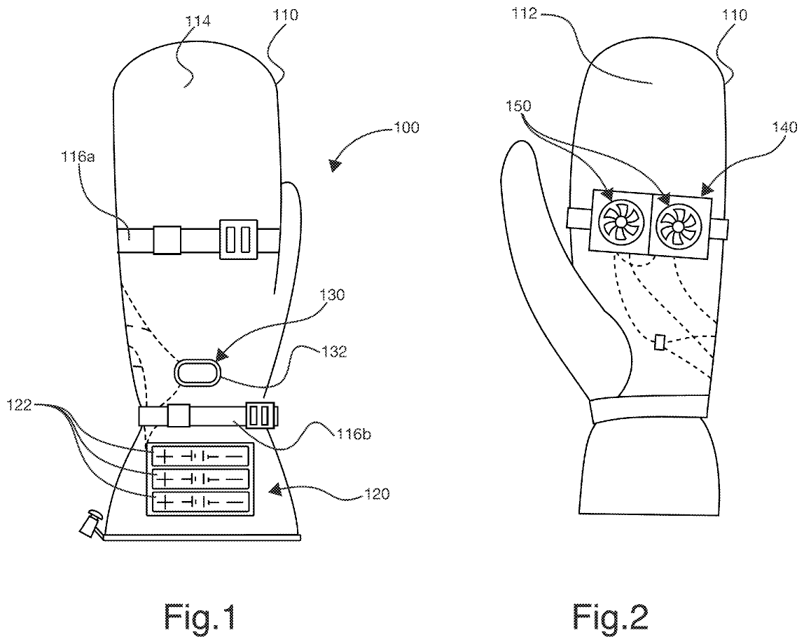

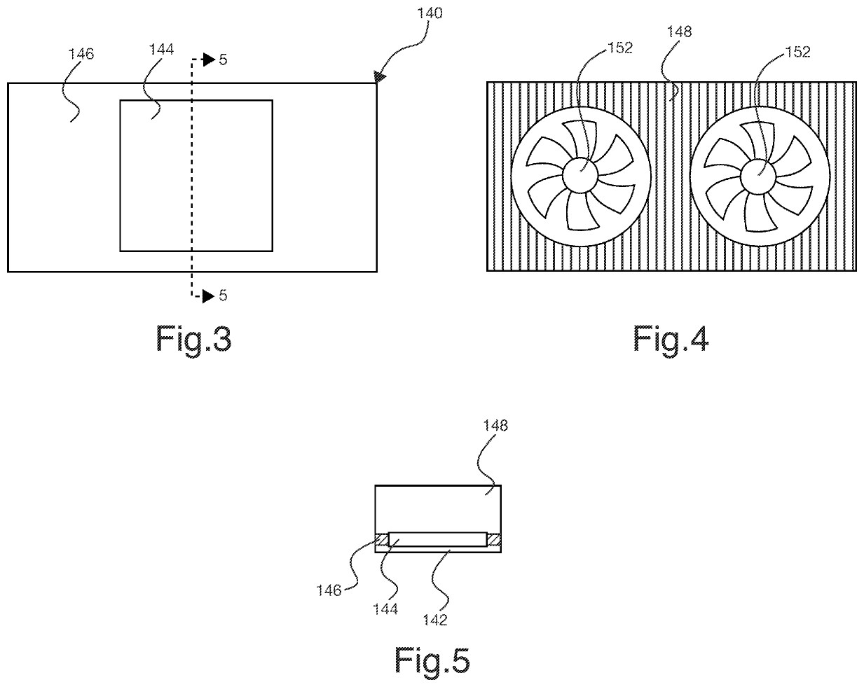

Turning now to the Figures, systems and methods for thermoelectric body temperature cooling according to the present invention can be seen. In FIGS. 1-5 below, an embodiment for a system 100 generally includes a Peltier device 140 and fan setup 150 affixed to a glove or mitten 110 and electrically connected to a power source 120 and power switch 130. The glove 110 may be any type of glove that is readily available, although a multilayered glove, such as a ski glove, is preferred for reasons that will be discussed below. The Peltier device 140 is preferably embedded into or otherwise extending through a palm side 112 of the glove 110, such that it is in contact or close to contact with the user's palm when the glove is worn. Alternatively, in embodiments in which the glove 110 is made of a thin material, the Peltier device 140 may be affixed to the palm side 112 of the glove 110 by a thermal adhesive.

The glove 110 further preferably includes a plurality of adjustable straps 116 for fitting and comfort. A hand strap 116a is preferably affixed to the Peltier device 140, allowing adjustment of how much contact the device 140 has with the user's palm. Additionally, a wrist strap 116b is preferably located near the base of the glove 110. Tightening this strap 116a acts to secure the glove 110 onto the user's hand and to prevent at least some air from entering the glove 110 during use. In a preferred arrangement the hand strap 116a is tightened to a higher tension than the wrist strap 116b. A looser wrist strap 116b may be used in an attempt to lessen mechanical constriction of blood flow through a user's wrist.

The power source 120 and the power switch 130 are preferably affixed to the back-of-the-hand side 114 of the glove 110 for ease of access during use and maintenance. The power source 120 is in electric communication with the switch 130, the Peltier device 140, and the fan setup 150 via wires. Preferably, the power source 120 is able to provide up to fifteen direct current volts to the system 100, although the system 100 preferably only needs ten volts to run efficiently. The power source 120 may preferably be one or more batteries 122 placed in a battery mount 124 capable of transferring power to the Peltier device 140 through the switch 130. In preferred embodiments, the batteries 122 are rechargeable (either removably rechargeable or charge-in-place), although non-rechargeable batteries are also contemplated. Some embodiments optionally feature a battery mount 124 further including an electronic port 124a (e.g. a USB port) to connect the power source 120 to an outside power source via a cable for easy charging.

The power switch 130 is preferably in electronic communication with the power source 120, the Peltier device 140, and the fan setup 150, such that one switch 130 can control power flow to the entire system 100. The switch 130 may be a toggle switch that the user flips from an off position to an on position or may be a button that the user presses to power the device on or off. The switch 130 further includes a display 132 to indicate to the user the status of the system 100. For example, some embodiments of the present invention may feature a display 132 composed of one or more LED lights that illuminate when the system is powered on.

The Peltier device 140 is preferably embedded in or otherwise extending through the palm side 112 of the glove 110, and may be secured using adhesive. Starting from the layer closest to the user's palm, the Peltier device 140 consists of one or more layers of a heat-conductive layer 142 (e.g., a heat-conductive metal), a thermoelectric cooler 144 (preferably surrounded by an insulation material 146), and a heatsink 148. The heat-conductive layer 142 is preferably a relatively thin sheet of thermally conductive metal (e.g. a sheet of copper), which acts to thermally transfer heat away from the palm and toward the thermoelectric cooler 144. When the hand strap 116a is adjusted, the user may decide how much to have the conductive metal layer 142 come in contact with the skin of the user's palm. For example, when the strap 116a is tightened, more of the conductive metal layer 142 will contact the palm, leading to a greater cooling effect on the palm when the system 100 is in use.

Additionally or alternatively, though depicted as a relatively flat layer 142, the heat-conductive layer may be contoured so as to provide maximum surface area contact with a user's palm. In fact, the layer may be formed according to a customized mold (or mandrel) having been obtained from a particular user. Further additionally or alternatively, the heat-conductive layer may be interchangeable, such that differing heat exchange rates may be selectively achieved. For instance, the heat-conductive layer may be made more or less efficient (e.g., by changing thickness and/or material) and selected and used based on a desired heat exchange rate for a particular use.

Affixed to the conductive metal layer 142 opposite to the user's palm via a thermal adhesive, the thermoelectric cooler 144 may be surrounded on all sides by an insulation material 146. The thermoelectric cooler 144 is preferably a device well known in the art (e.g. a TEC-12706, currently available from Hebei), which acts to create a temperature difference between one side, the cold side 144b, and the other, the hot side 144a. While in use, the thermoelectric cooler 144 draws heat away from the cold side 144b to the hot side 144a. In some thermoelectric coolers, this temperature difference can be up to 70 degrees Celsius. In embodiments of the present invention, the overall temperature difference is not consequential itself. However, the cold side 144b of the thermoelectric cooler 144 is preferably chilled to a temperature between 10 and 20 degrees Celsius. Most preferably, the cold side 144b is lowered to a temperature of about 15 degrees Celsius and kept at this temperature throughout use of the system 100. In use, the thermoelectric cooler 144 draws heat from the user's palm, through the conductive metal layer 142 and the cold side 144b, to the hot side 144a, thereby cooling the palm.

Preferably immediately surrounding the thermoelectric cooler 144 on all sides except the hot side 144a and the cold side 144b, the insulation material 146 acts to prevent heat from escaping the sides of the thermoelectric cooler 144, which may assist in limiting inadvertent exposure of or contact with the hot portion of the device. The insulation material 146 is preferably a thermally insulating material (e.g. a layer of rubber and/or foam) of at least approximately the same thickness as the thermoelectric cooler 144. In manufacturing, the insulation material 146 may be adhered to the sides of the thermoelectric cooler 144, except for the hot side 144a and cold side 144b, using an adhesive.

Following the layer of the thermoelectric cooler 144 and insulation material 146, the heatsink 148 is situated as the furthest layer of the Peltier device 140 from the palm side 112 of the glove 110. The heatsink 148 may be adhered to both the hot side 144a of the thermoelectric cooler 144 and the surrounding insulation material 146 using thermal adhesive, such that the heatsink 148 completely covers the other layers of the device 140. As the name implies, the heatsink 148 serves to safely absorb the heat collected by the hot side 144a of the thermoelectric cooler 144 and transfer it to ambient air. The heatsink 148 is preferably a conventional heatsink known in the art, and may be comprised of a single heatsink or multiple heatsinks.

Situated on the opposite side of the Peltier device 140 from the palm side 112 of the glove 110 (i.e. on the side facing away from the user's palm), the fan setup 150 serves to dissipate heated air away from the heatsink 148 and into the ambient air. The fan setup 150 may be one or more fans 152 in electronic communication with the power source 120 and power switch 130. The fans 152 may be any type of conventional fan that can move heated air away from the system 100, but generally is a heatsink fan that is readily commercially available. Fan blades of the fans 152 may be covered with a protective cage so as to prevent any inadvertent physical contact therewith.

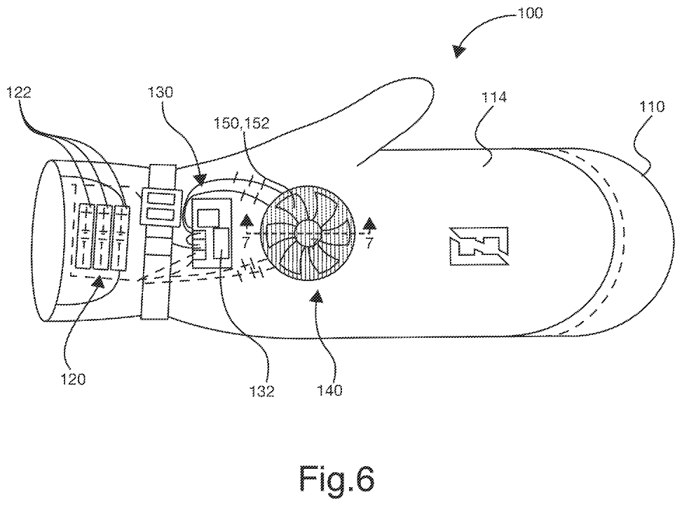

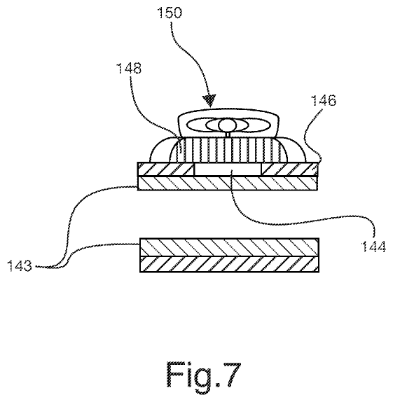

In some alternative embodiments of the present system 100, the Peltier device 140 and fan setup 150 may be located on the back-of-the-hand side 114 of the mitten 110 along with the power source 120 and power switch 130, as seen FIGS. 6-7 above. Additionally, the glove 110 may include a casing 143 covering the inside of the glove 110, preferably made of a thin layer of thermally conductive metal (e.g. a thin sheet of aluminum). The glove 110 may also lack the hand strap 116a of the system 100 above, however the wrist strap 116b is preferably included. The Peltier device 140 in such embodiments lacks the conductive metal layer 142, as the casing 143 within the glove 110 serves the same purpose. The Peltier device 140 is embedded in or otherwise extends through the glove 110. The cold side 144b of the thermoelectric cooler 144 is adhered to or at least in contact with the casing 143 to transfer heat away from the user's hand through the heatsink 148 and into the environment. In all other aspects, the Peltier device 140, fan setup 150, power source 120, and power switch 130 work as described above. An advantage of such embodiments would be that the system 100 may be in use while an activity is ongoing (e.g., an activity requiring use of a user's palm, such as a grip) or employed immediately after the activity is ceased.

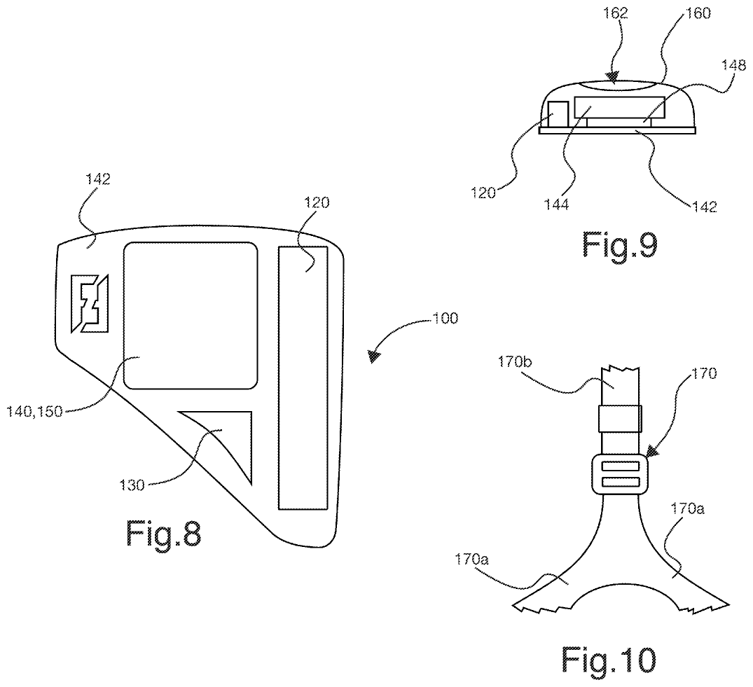

In an even further alternative embodiment of the present invention, the system 100 may lack a glove 110 entirely, as seen in FIGS. 8-10 above. While other components, such as the power source 120, power switch 130, and fan setup 150 preferably remain as described above in embodiments above, the layers of the Peltier device 140 may optionally be arranged slightly differently. For example, since the system 100 no longer has an entire glove on which to be arranged, the power source 120 and power switch 130 are preferably located near the Peltier device 140 to minimize size. In such arrangements, the conductive metal layer 142 of the Peltier device 140 may act as a base on which to place the system 100 components. Thus, the power source 120, power switch 130, and thermoelectric cooler 144 of the Peltier device 140 may be all be affixed to the conductive metal layer 142 using adhesive.

Further, the system 100 may optionally feature a cover 160. Preferably, this cover 160 is made of a durable material, such as a hard plastic, to protect the system 100 from wear during use, maintenance, and storage. Additionally, the cover 160 may protect the user from unwanted contact with the system 100. The cover 160 is preferably affixed just within the edges of the conductive metal layer 142, such that the rest of the components of the system 100 are within the cover 160 boundaries. Preferably, the cover 160 is dome shaped, where the dome reaches a height adequately above the fan setup 150 to allow the one or more fans 152 to spin uninhibited, yet not too high as to be impractical for use. The cover 160 also preferably includes an aperture 162 directly above the fan setup 150 to allow for heated air to escape out of the system 100 and into the environment.

Instead of a glove, this embodiment of the system 100 is preferably held in place by using a Y-shaped strap 170 affixed at each of the ends to the conductive metal layer 142 of the Peltier device 140. The strap 170 is so shaped to cooperate efficiently with a human hand. When worn, the two shorter legs 170a of the strap 170 are situated between fingers on the hand. For example, one leg 170a may be situated between the pointer finger and the thumb of the user, while the other may be situated between the middle and ring finger. The longer leg 170b, meanwhile, loops around the side of the hand below the pinky. In this way, the system may be affixed to the palm of the hand in a comfortable way for the user to wear. As was the case in other embodiments, the heat-conductive metal layer 142 is preferably held in place in contact with the palm of the user, while the fan setup 150, and in this embodiment the cover 160, face away from the palm. Finally, the strap 170 is preferably adjustable, such that the conductive metal layer 142 may be tightened or loosened against the palm, to allow for comfort and preference of the user.

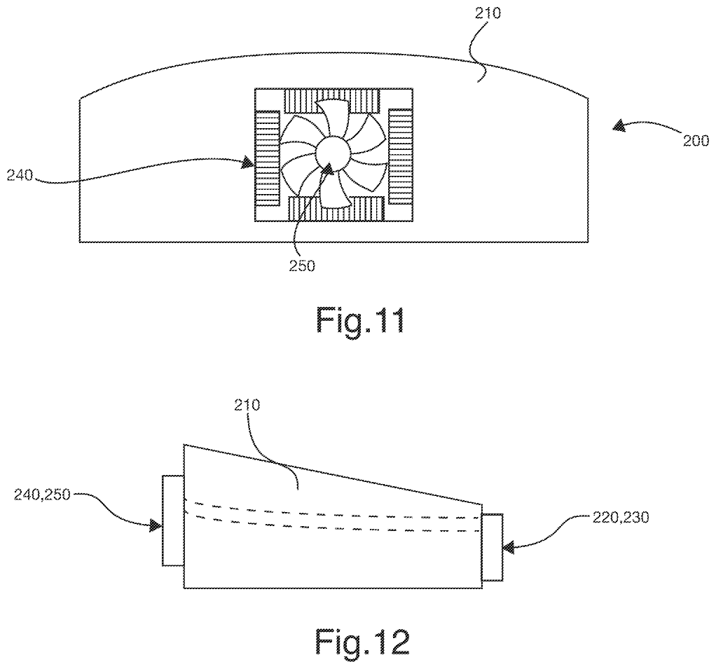

Some other alternative embodiments of the present invention may be described with reference to a forehead centric system 200, as seen in FIGS. 11 and 12 above. Using the same numbering conventions as the system 100 described above, this system 200 generally features a headband 210 with an embedded Peltier device 240, an affixed power source 220 and power switch 230, and a fan setup 250. The Peltier device 240, which preferably features substantially the same composition as in the system 100 described above, is embedded in the headband 210, such that the conductive metal layer 242 is in contact with the forehead of the user when the headband 210 is worn. In all other aspects, the Peltier device 240 and fan setup 250 work as described above to draw heat away from the skin of the user and dissipate it into the environment. The power source 220 and the power switch 230 also work as described above, however in this system 200 they are located on an environment side 212 of the headband 210 to be accessed while the headband 210 is worn. The headband 210 may be one of elastic material, frictionally adjustable (e.g., friction buckle), and discretely positionally adjustable (e.g., snap strap or pin buckle).

This strap-supported system 200 may also be used on a foot of a user, the cold side of the Peltier device being positioned on a sole of a foot, such as a foot that has been elevated on a footrest or ottoman. The headband 210 may then be adjusted to support the system 200 on the foot.

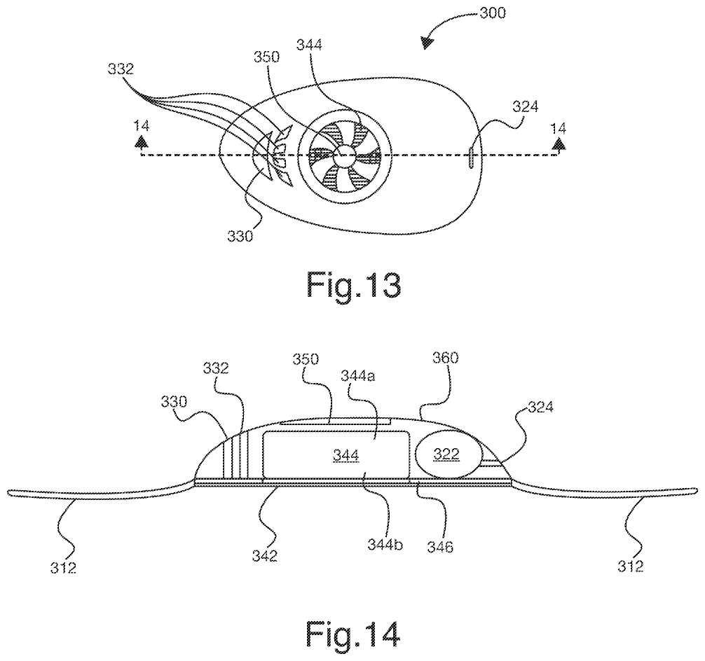

Turning to FIGS. 13 and 14, an alternative embodiment of a system for thermoelectric body cooling can be seen. The system 300 is generally similar to the first system 100 mentioned above, such that like parts have similar numbers. For example, like the system 100 above, the system 300 may pair with a glove 310, wherein the system 300 is embedded into the glove 310 and an adjustable hand strap 312 may be used to hold the system 300 in place against the user's hand.

The system 300 also generally includes the same parts as the system 100 in a new design and includes the addition of cover 360. The cover 360 may be a durable material, such as molded or injected plastic, that generally fits over the Peltier device 340, fan 350, and power source 320. The cover 360 also preferably includes a releasable snap mechanism to lock the cover 360 into place, such that the cover 360 will not fall off during use. In the system 300, the cover 360 includes holes through which the power switch 330, the LED display 332, the fan 350, and power source 320 may be seen and/or accessed. In particular, preferred embodiments of the system 300 include a push button power switch 330 that is accessible from outside the cover 360, allowing a user to turn on the system 300 without removing the cover 360.

Further, the display 332 preferably includes LED lights that display the energy left in the battery, wherein the lights glow green for a full or near full energy level, yellow for near-half energy, and red for low or zero energy. Thus, the user may be able to see the battery level of the system 300 through the display 332 without removing the cover 360. The fan 350 is preferably accessible through the cover, such that it may help expel excess heat from the Peltier device 340 when the device is in use. As explained above, the Peltier device 340 draws heat away from a cold side 344b of a thermoelectric cooler 344 towards a hot side 344a. The hot side 344a then expels the heat by heating the air around the thermoelectric cooler 344. The fan 350 expels this hot air from the system 300.

Finally, the power source 320 of the system 300 is preferably one or more rechargeable batteries 322, wherein the batteries 322 have the ability to be connected to a wall outlet to recharge. Thus, the battery 322, and by extension the cover 360, preferably includes an accessible charging port 324, wherein the user may connect the system 300 to an outlet to recharge the battery 322.

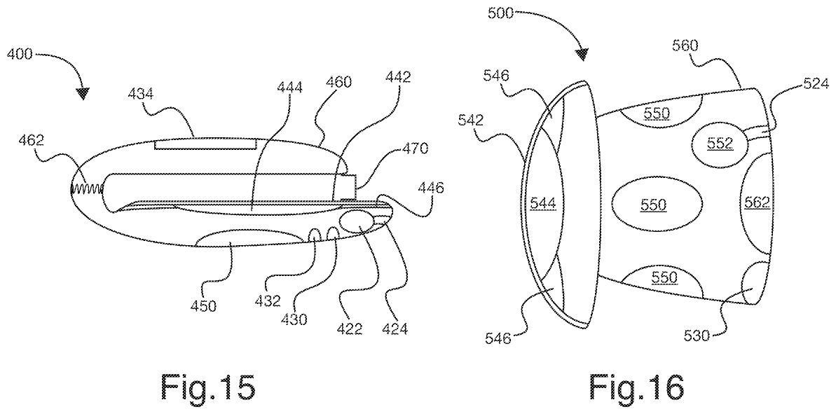

Turning to FIGS. 15 and 16, an alternative embodiment of a system for thermoelectric body cooling can be seen. The system 400 is generally similar to the systems 100 and 300 mentioned above, such that like parts have similar numbers. Thus, the system 400 preferably includes a power source 420, a power switch 430, a Peltier device 440, one or more fans 450, and a cover 460. However, unlike systems 100 and 300, the system 400 does not require use of a glove.

Instead, the cover 460 is preferably c-shaped, with a spring-biased hinge 462 at the curve of the c-shape, leaving a gap 470 defined within the c-shape. In use, the user's hand is inserted into gap 470 of system 400. Generally, the system 400 may be positioned comfortably between the thumb and forefinger, although the exact positioning of the system 400 on the hand is up to the user. The spring-biased hinge 462 ensures that the two ends of the cover 460 are in close proximity. Thus, when worn, the system 400 fits snug to the user's hand. The cover 460 also preferably includes airflow holes 464 that allow heated air from the thermoelectric cooler 444 to be expelled from the system 400, partially or completed by the fan 450.

Further, the system 400 preferably includes at least two types of displays. Like the systems 100 and 300, the system 400 preferably includes a battery power display 432. The battery power display 432 may comprise LED lights that convey the amount of battery power left in the rechargeable battery 422. The system 400 also preferably includes an interactive user display 434. The interactive user display 434 may be an input and output display, such as a touchscreen, LCD screen, and/or button control, or simply an output display to convey information to the user such as wear time. In embodiments wherein the interactive user display 434 has input capabilities, the user may be able to control the temperature of the device, set timers for use, and/or track workout metrics through the user display 434, among other possible capabilities.

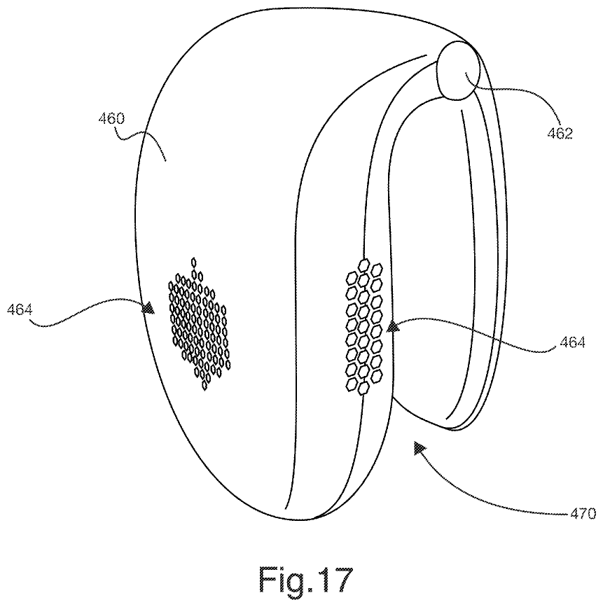

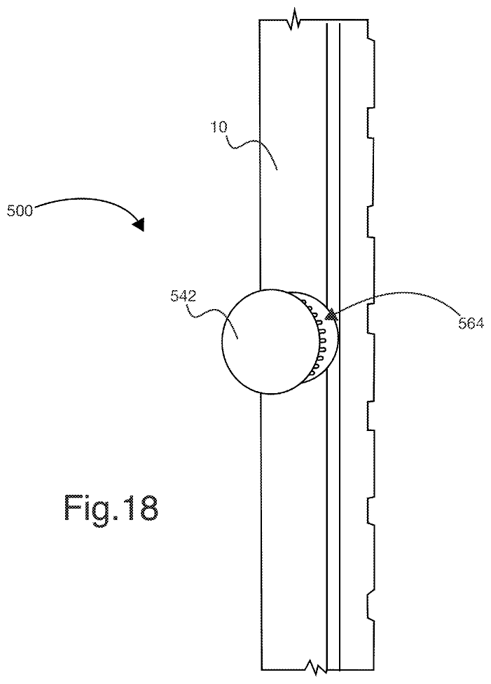

Turning to FIGS. 17 and 18, another alternative embodiment of a system for thermoelectric body cooling can be seen. The system 500 is generally similar in make-up to the systems 100, 300, and 400 mentioned above, such that like parts have similar numbers. Thus, the system 500 preferably includes a power source 520, a power switch 530, a Peltier device 540, a fan 550, and a cover 560. Like system 400, the system 500 does not require use of a glove. However, unlike the systems 100, 300, and 400, the system 500 does not need to be in constant contact with a user's hand.

Instead, the system 500 preferably includes a rack mount design, wherein the cover 560 includes a magnet 562 that may be used to suspend the system 500 from a metal weight rack 10. The magnet 562 is preferably situated proximate the hot side 544a of the thermoelectric cooler 544 in the Peltier device 540, such that cool side 544b of the thermoelectric cooler 544 is unobstructed from access by the user (except, perhaps, by the cover 560, but the cover 560 is preferably not temperature resistant, allowing it to reach the same cold temperature as the cool side 544b). Cover 560 also preferably includes airflow holes 564, which may allow heated air to escape from the system 500.

In use, a user may mount the system 500 to a piece of workout equipment made out of magnetic material, such as a squat rack 10, through the use of the magnet 562, or other mounting mechanism, such as a strap. This both acts as a way to store the system 500 when the user is not using it and it supports the system 500 when the user does use it. For example, the user may activate the power switch 530 to create a cool surface on the cover 560 facing away from the workout equipment. The user may then place their palm on the cool cover 560 to lower their internal body temperature and aid in the recovery process, just as the other systems 100, 300, and 400 work. This system 500 is unique in that it does not require the user to physically wear the system, rather the system may be mounted elsewhere and the user may make contact with the system whenever they desire.

In use one or more systems according to the present invention, in one or more embodiments thereof, may be used simultaneously by a user. For instance, one or more hand-supported embodiments may be utilized at the same time as a head-supported embodiment, foot-supported embodiments, or outside environment-supported embodiments. Additionally or alternatively, predetermined cooling regimens may be formulated. These predetermined cooling regimens may be particularized for a given user, and/or the embodiment(s) being used, and/or a given exercise, and/or a given body temperature, which may be acquired using commercially available thermometers. A cooling regimen may include specified cooling times and voltage settings.

The foregoing is considered as illustrative only of the principles of the invention. Furthermore, because numerous modifications and changes will readily occur to those skilled in the art, it is not desired to limit the invention to the exact construction and operation shown and described. While the preferred embodiment has been described, the details may be changed without departing from the invention, which is defined by the claims.

I claim:

1. A system for thermoelectrically cooling a human body, the system comprising:
a power source;
a Peltier device mounted on an article to be worn on the human body, the device comprising:
one or more conductive layers;
a thermoelectric cooler; and
a heatsink;
at least one fan; and
a power switch to control a supply of electrical current from the power source to at least one of the Peltier device and the at least one fan.

2. The system according to claim 1, wherein the Peltier device further comprises at least one layer of insulation material.

3. The system according to claim 1, wherein the power source comprises at least one rechargeable battery.

4. The system according to claim 3, wherein the power switch comprises a button.

5. The system according to claim 4, further comprising a non-interactive display.

6. The system according to claim 5, wherein the article comprises a glove.

7. The system according to claim 6, wherein the glove further comprises an adjustable strap.

8. The system according to claim 5, further comprising an adjustable strap for supporting the article on the human body.

9. The system according to claim 5, wherein the article comprises a headband.

10. A system for thermoelectrically cooling a human body, the system comprising:
a power source;
a power switch;
a Peltier device comprising:
one or more conductive layers;
a thermoelectric cooler; and
a heatsink;
one or more fans; and
a cover.

11. The system of claim 10, wherein the cover comprises at least one airflow hole.

12. The system according to claim 10, wherein the cover further comprises an interactive display.

13. The system according to claim 12, wherein the cover is substantially c-shaped and the cover further comprises a hinge opposite an open slot.

14. The system according to claim 13, wherein the slot is configured to receive a hand of the human to support the Peltier device on one of a palmar side and a dorsal side of the hand and to support the power source on the other of the dorsal side and the palmer side.

15. The system according to claim 10, further comprising a magnet secured to the cover.

16. A method for cooling blood flowing through a living human body, the method comprising the step of:
contacting an electrically operated Peltier device with an area of a living human body.

17. The method according to claim 16, further comprising supporting the Peltier device against the area by mounting an article to the human body.

18. The method according to claim 16, wherein the area of the living human body is selected from the group consisting of a palm of a hand and a forehead.

19. The method according to claim 16, wherein the Peltier device is secured at least substantially within a rigid cover, the rigid cover containing a fan and a power source for supplying electrical power to the Peltier device and the fan.

20. The method according to claim 19, further comprising the step of mounting the rigid cover to a support structure using a magnet.
